(19) United States
(12) Patent Application Publication
(10) Pub. No.: US 2018/0267180 A1
(43) Pub. Date: Sep. 20, 2018

(54) RADIATION DETECTION ELEMENT AND RADIATION DETECTION APPARATUS

(71) Applicant: Kabushiki Kaisha Toshiba, Minato-ku (JP)

(72) Inventor: Keiji SUGI, Fujisawa (JP)

(73) Assignee: Kabushiki Kaisha Toshiba, Minato-ku (JP)

(21) Appl. No.: 15/691,288

(22) Filed: Aug. 30, 2017

(30) Foreign Application Priority Data
Mar. 17, 2017 (JP) 2017-052296

(51) Int. Cl. G01T 1/24; G01T 1/20; H01L 27/30; H01L 51/42; H01L 51/44

(52) U.S. Cl. CPC G01T 1/241; G01T 1/2018; H01L 51/0064; H01L 51/4253; H01L 51/442; H01L 27/308

(57) ABSTRACT

Disclosed is a radiation detection element including: an organic layer configured to generate an electric charge by receiving an incident radioactive ray; a first electrode layer arranged in one side of the organic layer; and a second electrode layer arranged in the other side of the organic layer to face the first electrode layer and provided with a first electrode pattern and a second electrode pattern spaced from the first electrode pattern.

### CROSS-REFERENCE TO RELATED APPLICATION

This application is based upon and claims the benefit of priority from the prior Japanese Patent Application No. 2017-052296 filed in Japan on Mar. 17, 2017; the entire contents of which are incorporated herein by reference.

### FIELD

Embodiments described herein relate generally to a radiation detection element and a radiation detection apparatus.

### BACKGROUND

In recent years, as a detection apparatus used detect a radioactive ray, an apparatus provided with a semiconductor detection element has been proposed. The semiconductor detection element has a smaller size, a lower driving voltage, and better responsiveness, compared to a Geiger-Muller tube (GM tube) of the prior art. The semiconductor detection element has, for example, a scintillator that converts a radioactive ray into light and a semiconductor layer that generates an electric charge in response to the light from the scintillator.

In this type of the semiconductor detection element, an effective area for detecting radioactive rays increases as its size increases. Therefore, a radioactive ray can be detected across a wide range. However, as the size of the element increases, a signal-to-noise (SN) ratio of the semiconductor detection element is degraded disadvantageously.

### BRIEF DESCRIPTION OF THE DRAWINGS

FIG. 1 is a perspective view illustrating a radiation detection element according to an embodiment;

FIG. 2 is a diagram schematically illustrating a X-Z cross section of the radiation detection element;

FIG. 3 is a plan view illustrating an electrode layer;

FIG. 4 is a perspective view illustrating arrangement of the electrode layer;

FIG. 5 is a block diagram schematically illustrating a configuration of the control circuit;

FIG. 6 is a diagram illustrating a relationship between a size of the radiation detection element and a SN ratio.

FIG. 7 is a diagram for describing an electrostatic capacity between the electrode layers;

FIG. 8 is a diagram illustrating a relationship between a line width of a line pattern and a capacitor ratio;

FIG. 9 is a diagram illustrating an electric potential distribution between the electrode layers;

FIG. 10 is a diagram illustrating an electric potential distribution between the electrode layers;

FIG. 11 is a diagram illustrating an electric potential distribution between the electrode layers;

FIG. 12 is a perspective view illustrating a radiation detection apparatus according to the embodiment;

FIG. 13 is an exploded perspective view illustrating a detection unit;

FIG. 14 is a perspective view illustrating a radiation detection element;

FIG. 15 is a block diagram illustrating a circuit configuration of the radiation detection apparatus;

FIG. 16 is a diagram for describing an example of using the radiation detection apparatus;

FIG. 17 is a diagram illustrating a modification of the electrode layer;

FIG. 18 is a diagram illustrating a modification of the electrode layer; and

FIG. 19 is a diagram illustrating a modification of the radiation detection element.

### DETAILED DESCRIPTION

A radiation detection element according to an embodiment includes an organic layer that generates an electric charge by receiving an incident radioactive ray, a first electrode layer arranged in one side of the organic layer, and a second electrode layer arranged in the other side of the organic layer to face the first electrode layer, the second electrode layer having a first electrode pattern and a second electrode pattern spaced from the first electrode pattern.

Embodiments of a present disclosure will now be described with reference to the accompanying drawings. In the following description, an XYZ coordinate system consisting of X, Y, and Z axes perpendicular to each other is employed as appropriate. In addition, thicknesses or sizes of substrates or each layer stacked on the substrate illustrated in the reference drawings are illustrated schematically or exaggeratingly, and they may not necessarily match real thicknesses or sizes.

### First Embodiment

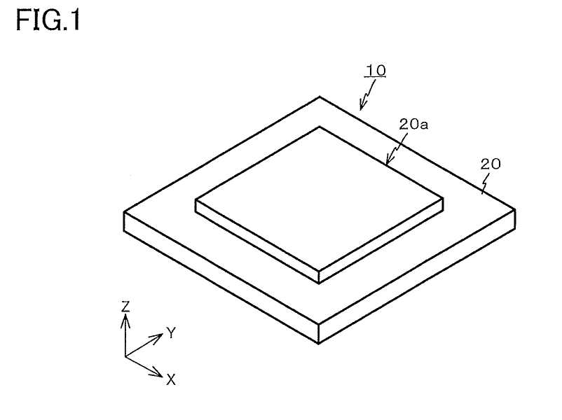

FIG. 1 is a perspective view illustrating a radiation detection element 10 according to a first embodiment of the disclosure. As illustrated in FIG. 1, the radiation detection element 10 has a substrate 20 and a multilayered element portion 20a formed on the substrate 20. The radiation detection element 10 is a chip of which one side has a length of approximately 10 mm.

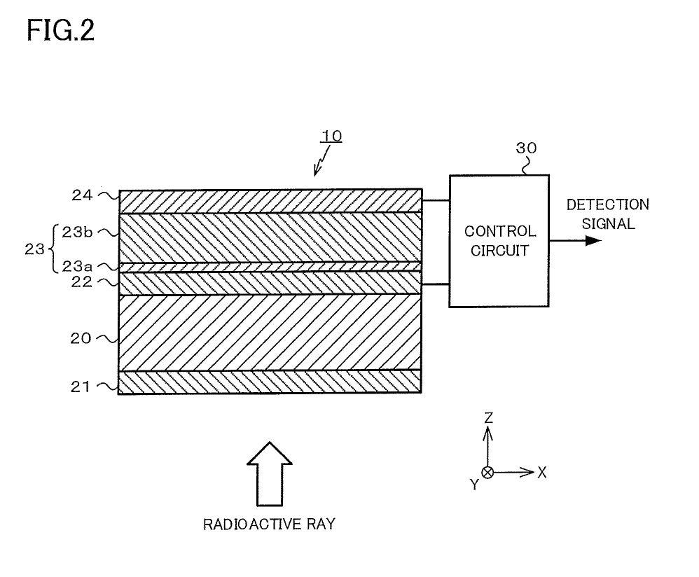

FIG. 2 is a diagram schematically illustrating an X-Z cross section of the radiation detection element 10. As illustrated in FIG. 2, the radiation detection element 10 has a substrate 20, a scintillator layer 21 provided on a lower surface of the substrate 20, electrode layers 22 and 24 stacked on an upper surface of the substrate 20, and an organic layer 23.

The substrate 20 is a rigid substrate formed of, for example, transparent resin. The electrode layer 22, the organic layer 23, and the electrode layer 24 are stacked on the upper surface of the substrate 20 in this order. The scintillator layer 21 is formed on the lower surface of the substrate 20.

The scintillator layer 21 is a layer that emits light in response to an incident radioactive ray. The organic layer 23 is excited by light from the scintillator layer 21. For this reason, a composition of the scintillator layer 21 is determined on the basis of compatibility with the organic layer 23. For example, the scintillator layer 21 is formed of a material including cesium iodide CsI, iodine I, cesium Cs, and thallium Tl. The scintillator layer 21 is excited in response to an incident radioactive ray and emits green light. The scintillator layer 21 is formed, for example, through vapor deposition.

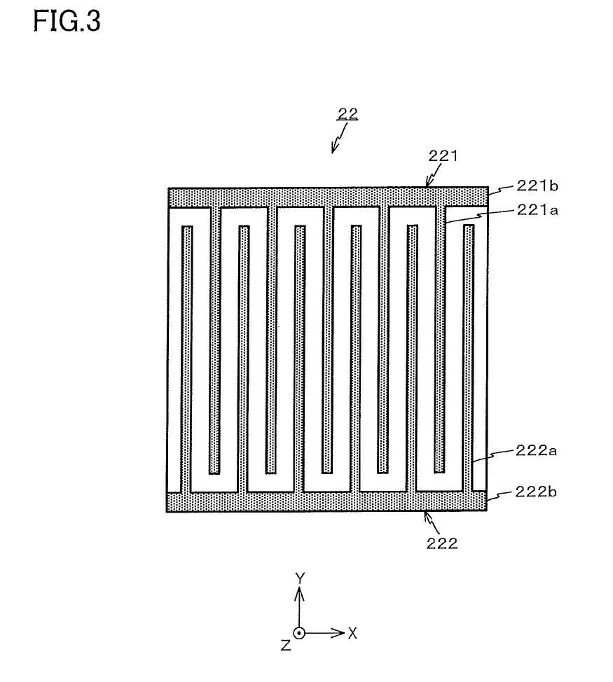

The electrode layer 22 is formed of, for example, metal such as copper (Cu). FIG. 3 is a plan view illustrating the electrode layer 22. As illustrated in FIG. 3, the electrode layer 22 has a pair of electrode patterns 221 and 222 formed in a comb tooth shape.

The electrode pattern 221 includes a plurality of line patterns 221a extending in parallel with the Y-axis and line patterns 221b that extend in parallel with the X-axis and are connected to an +Y-side end portion of the line pattern 221a. In addition, the electrode pattern 222 includes a plurality of line patterns 222a extending in parallel with the Y-axis and line patterns 222b that extend in parallel with the X-axis and are connected to an −Y-side end portion of the line pattern 221a. The line pattern 221a of the electrode pattern 221 and the line pattern 222a of the electrode pattern 222 are arranged along the X-axis in an alternating manner at equal intervals. The line patterns 221a and 222a have a line width of approximately 1 μm, and an arrangement pitch of the line patterns 221a and 222a is set to approximately 8 μm.

The electrode patterns 221 and 222 may be formed, for example, by providing a copper foil on the upper surface of the substrate 20 and etching the copper foil.

Returning to FIG. 2, the organic layer 23 is stacked on the upper surface of the electrode layer 22. The organic layer 23 has a thickness of approximately 100 nm and includes two parts including an organic intermediate layer 23a formed on the upper surface of the electrode layer 22 and an organic semiconductor region 23b provided on the upper surface of the organic intermediate layer 23a. The organic layer 23 serves as a photoelectric conversion layer.

The organic semiconductor region 23b is formed of a first compound and a second compound. The first compound contains a first subphthalocyanine derivative (SubPc), and the second compound contains a second subphthalocyanine derivative (F5-SubPc). The first compound forms an n-type semiconductor layer, and the second compound forms a p-type semiconductor layer. A boundary between the p-type semiconductor layer and the n-type semiconductor layer has a bulk heterojunction structure in which the first compound of the p-type semiconductor layer and the second compound of the n-type semiconductor layer are mixed with each other.

The amount of the first compound of the organic semiconductor region 23b is substantially equal to the amount of the second compound. In addition, a concentration of the first compound is 0.5 to 1.5 times of the concentration of the second compound. The concentration is a value expressed as a volume concentration or a volume ratio. For example, the volume ratio of the first compound may be set to be equal to or higher than 0.45 and equal to or lower than 0.55, and the volume ratio of the second compound may be set to be equal to or higher than 0.45 and equal to or lower than 0.55.

At least a part of the organic semiconductor region 23b preferably has an amorphous structure. If at least a part of the organic semiconductor region 23b has an amorphous structure, homogeneity of the organic semiconductor region 23b is improved.

The organic semiconductor region 23b configured as described above contains a subphthalocyanine derivative. For this reason, absorptance of the organic semiconductor region 23b for green light is improved. A wavelength (peak wavelength) of the light in the high absorptance depends on a material of the organic semiconductor region 23b. For this reason, a composition of the organic semiconductor region 23b is preferably determined considering compatibility with the composition of the scintillator layer 21. In the radiation detection element 10, the scintillator layer 21 contains cesium iodide CsI, and the organic semiconductor region 23b contains a subphthalocyanine derivative.

The organic intermediate layer 23a has a thickness of approximately 5 to 50 nm and is placed between the organic semiconductor region 23b and the electrode layer 22. The organic intermediate layer 23a suppresses inactivation of electric charges generated from the organic semiconductor region 23b. For this reason, it is possible to improve detection sensitivity of the pulse current caused by electric charges generated from the organic intermediate layer 23a. In addition, the thickness of the organic intermediate layer 23a is smaller than that of the organic semiconductor region 23b. For this reason, even when the organic intermediate layer 23a is provided in the organic layer 23, it is not necessary to excessively increase a bias voltage applied to the organic layer 23.

The organic intermediate layer 23a and the organic semiconductor region 23b may be formed, for example, through vapor deposition.

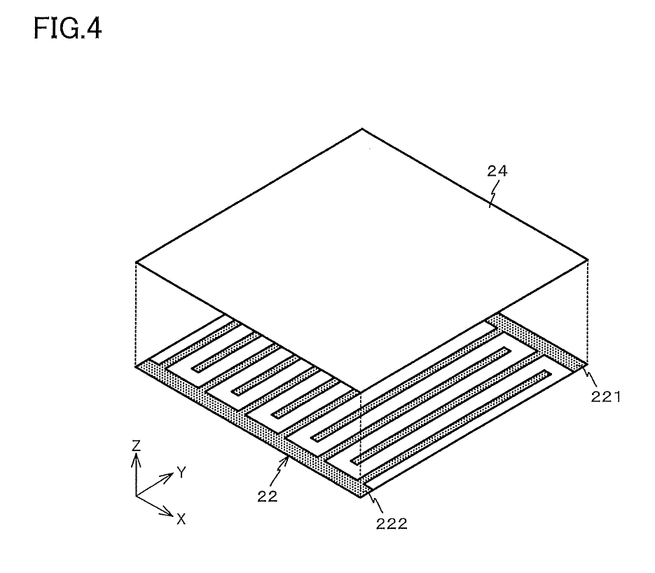

The electrode layer 24 is formed of metal such as copper (Cu). FIG. 4 is a perspective view illustrating arrangement of the electrode layers 22 and 24. As illustrated in FIG. 4, the electrode layer 22 is provided to face the electrode patterns 221 and 222 of the electrode layer 24. The electrode layer 24 may be formed on an upper surface of the organic layer 23 using various methods such as screen printing.

In the radiation detection element 10 configured as described above, a stable sealing material such as glass is coated on the upper and lower surfaces of the substrate 20 to cover each layer of the element portion 20a.

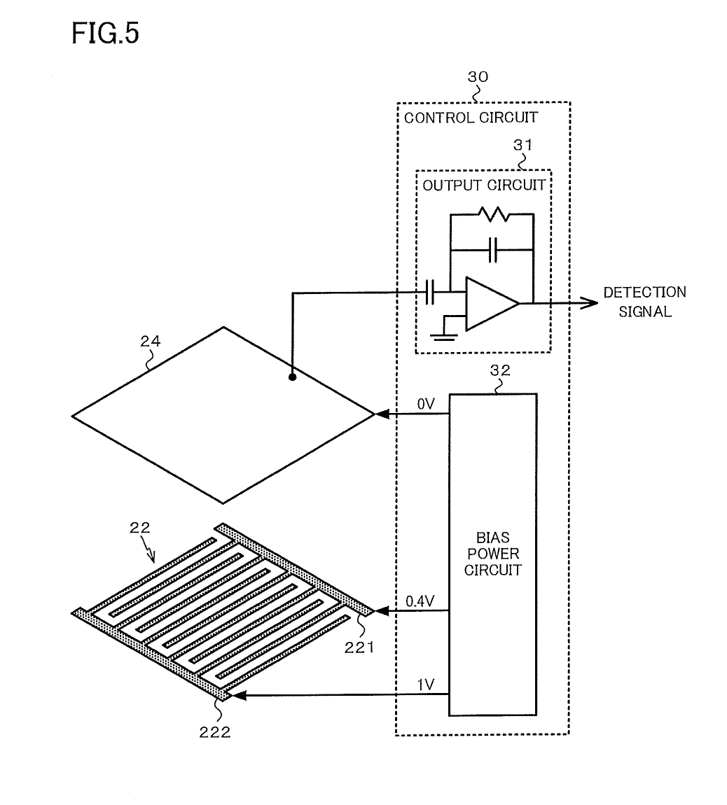

As illustrated in FIG. 2, the control circuit 30 is connected to the radiation detection element 10. FIG. 5 is a block diagram illustrating a schematic configuration of the control circuit 30. As illustrated in FIG. 5, the control circuit 30 has an output circuit 31 and a bias power circuit 32.

The bias power circuit 32 is connected to the electrode layer 24 and the electrode patterns 221 and 222 of the electrode layer 22. The bias power circuit 32 applies a voltage to the electrode layers 24 and 22 such that the electrode layer 24 has an electric potential of 0 V, the electrode pattern 221 has an electric potential of 0.4 V, and the electrode pattern 222 has an electric potential of 1 V.

The output circuit 31 is, for example, a differential circuit consisting of an operational amplifier, a resistor, a capacitor, and the like. The output circuit 31 outputs a detection signal having a voltage corresponding to electric charges arriving at the electrode layer 24.

The control circuit 30 provided with the output circuit 31 and the bias power circuit 32 is installed, for example, in the substrate 20 of FIG. 1.

Next, operations of the radiation detection element 10 configured as described above will be described. For example, as a radioactive ray is incident to the scintillator layer 21 as indicated by the white arrow of FIG. 2, the scintillator layer 21 emits green light. The light from the scintillator layer 21 is incident to the organic layer 23 through the substrate 20 and the electrode layer 22. The organic layer 23 generates a movable electric charge by virtue of energy of the incident light. This electric charge increases the voltage of the electrode layer 24.

As the voltage of the electrode layer 24 increases, the control circuit 30 outputs a detection signal having a value corresponding to an increase of the voltage. The detection signal is a pulse signal having a value that steeply increases in synchronization with the incidence timing of the radioactive ray. Therefore, it is possible to measure an intensity of the radioactive ray incident to the radiation detection element 10 by counting the number of pulses of the detection signal.

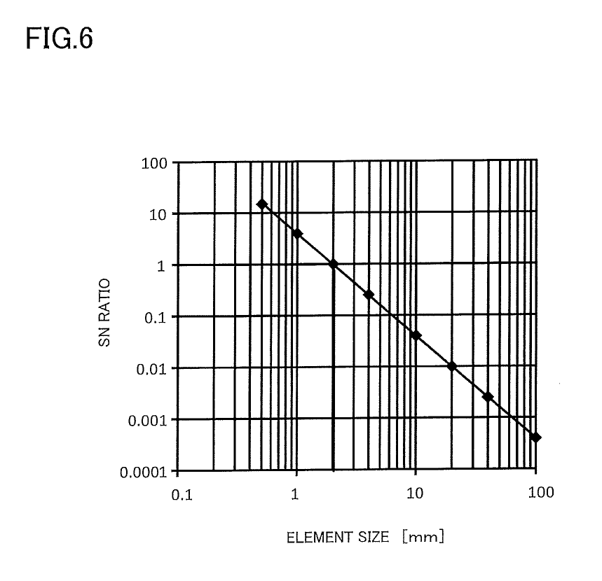

FIG. 6 is a diagram illustrating a relationship between the size of the radiation detection element 10 and the SN ratio. In general, as the size of the radiation detection element 10 increases, the area of the scintillator layer 21 increases accordingly. For this reason, an effective area for detecting a radioactive ray increases. However, as the size of the radiation detection element 10 increases, the SN ratio decreases as illustrated in FIG. 6. Note that the element size of FIG. 6 refers to a dimension of one side of the radiation detection element.

For example, a radiation detection element of the prior art has a size of approximately 2 mm. With respect to this size, if the size of the radiation detection element has 10 mm, the SN ratio decreases to 1/10 or smaller. The SN ratio depends on a capacity of the radiation detection element (element capacity). As the element capacity increases, the SN ratio decreases accordingly.

Therefore, it can be said that the radiation detection element has a tradeoff relationship between enlargement of the effective area and improvement of the SN ratio. Using the radiation detection element 10 according to this embodiment, it is possible to achieve both enlargement of the effective area of the radiation detection element and improvement of the SN ratio. A principle thereof will now be described.

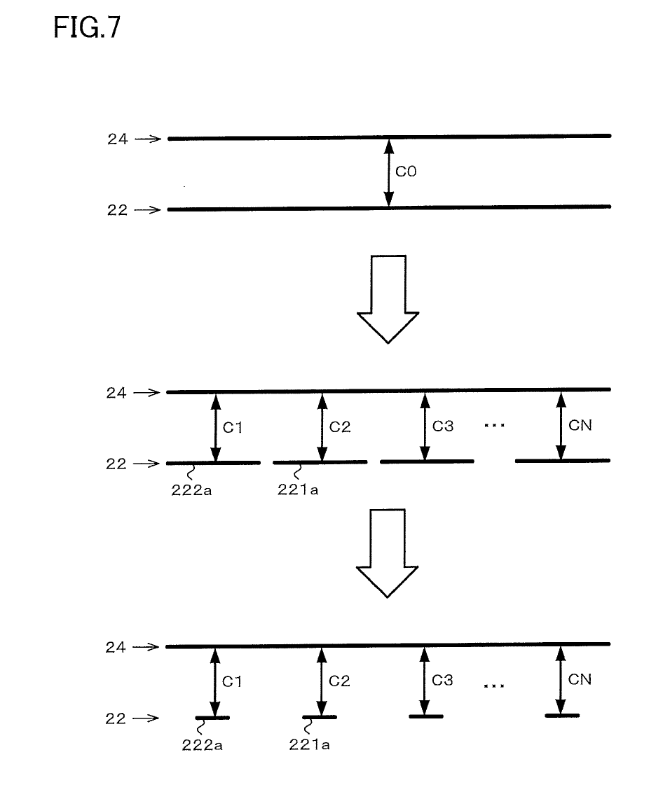

The element capacity of the radiation detection element is determined by an electrostatic capacity between the electrode layers 22 and 24. For example, FIG. 7 is a diagram for describing the electrostatic capacity between the electrode layers 22 and 24. As illustrated in FIG. 7, it is assumed that the electrostatic capacity between the electrode layers 22 and 24 having the same shape is set to “C0.” As schematically illustrated in FIG. 7, the electrostatic capacity can be reduced by dividing the electrode layer 22 into a plurality of line patterns. For example, the electrostatic capacity obtained by dividing the electrode layer 22 into “N” line patterns becomes a sum ΣC (=C1+C2+ . . . +CN) of the electrostatic capacities C1 to CN between each line pattern and the electrode layer 24. This electrostatic capacity ΣC is smaller than the electrostatic capacity C0. In addition, if the line width of the line pattern is further reduced, the electrostatic capacity ΣC is also reduced accordingly.

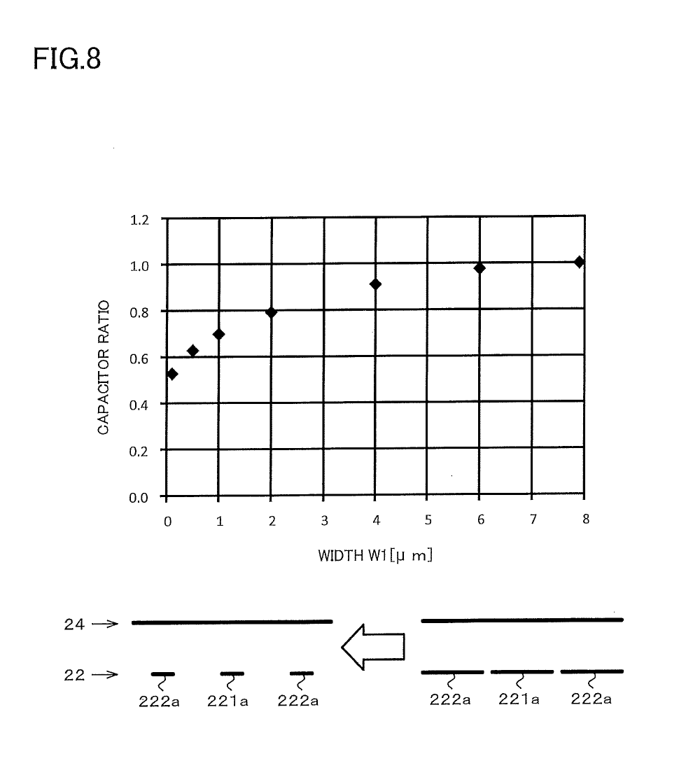

For example, in the radiation detection element 10 according to this embodiment illustrated in FIG. 3, the arrangement pitch of the line patterns 221a and 222a is set to 8 μm. It is assumed that the line width of the line patterns 221a and 222a is set to 8 μm. In this case, the line width is equal to the pitch. Therefore, the electrode layers 22 and 24 have substantially the same area. If the line width of the line patterns 221a and 222a is reduced gradually from this state, the electrostatic capacity also decreases gradually. FIG. 8 is a diagram illustrating a relationship between the line width W1 of the line patterns 221a and 222a and the capacitor ratio. The capacitor ratio refers to a ratio of the electrostatic capacity ΣC with respect to the electrostatic capacity Cmax at which the element capacity of the radiation detection element 10 is maximized.

As recognized from FIG. 8, the capacitor ratio, that is, the electrostatic capacity ΣC decreases by reducing the line width of the line patterns 221a and 222a. As a result, the element capacity of the radiation detection element 10 is reduced. In the radiation detection element 10 according to this embodiment, the line width of the line patterns 221a and 222a is set to approximately 1 μm. Therefore, compared to a case of the prior art in which the electrode layers 22 and 24 have the same pattern (solid pattern), only the element capacity is reduced by 30% while the element size is maintained. As a result, it is possible to improve the SN ratio as much as a decrease of the element capacity without changing the element size.

By forming the electrode layer 22 provided with the line patterns 221a and 222a having a line width of 1 μm and an arrangement pitch of 8 μm as described above, it is possible to reduce the element capacity. However, in a case where a bias voltage is applied between the electrode layers 22 and 24 such that the line patterns 221a and 222a have the same electric potential, only the area where the line patterns 221a and 222a overlap with the electrode layer 24 predominantly contributes to detection of radioactive rays.

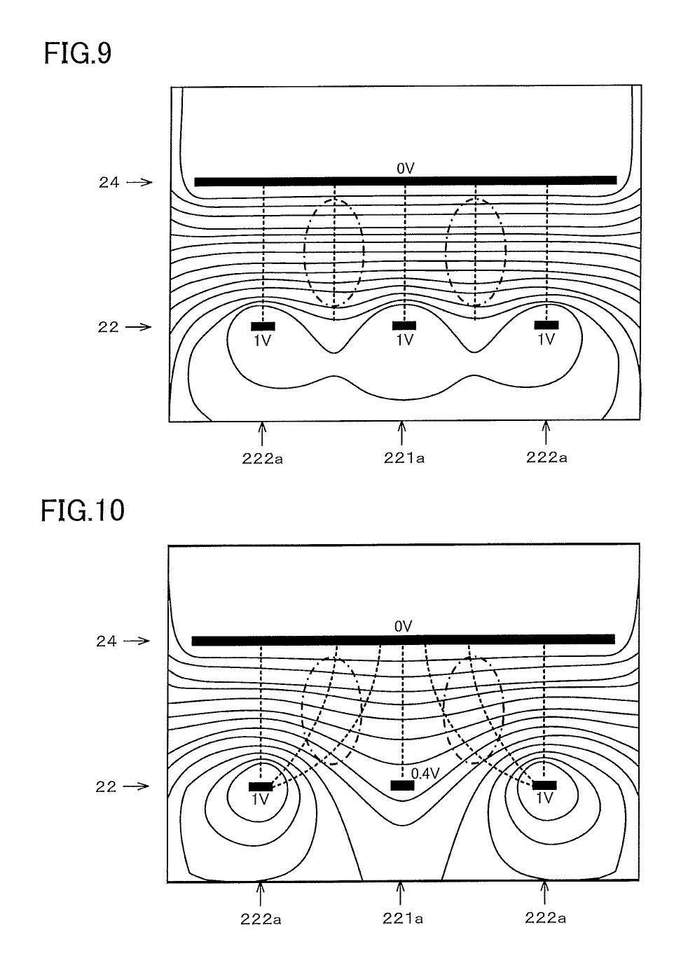

FIG. 9 is a diagram illustrating an electric potential distribution between the electrode layers 22 and 24. The example of FIG. 9 shows an electric potential distribution obtained by applying a bias voltage to the electrode layers 22 and 24 such that the electric potentials of the line patterns 221a and 222a of the electrode layer 22 become 1 V, and the electric potential of the electrode layer 24 becomes 0 V. As illustrated in FIG. 9, if both the line patterns 221a and 222a have the same electric potential of 1 V, an electric potential distribution between the electrode layers 22 and 24 becomes substantially uniform. In this case, an electric charge between the electrode layers 22 and 24 moves along the dotted line. Therefore, an electric charge moves only to a region between the line patterns 221a and 222a and the electrode layer 24, and an electric charge does not easily move to a region surrounded by the virtual line in the drawings.

In this regard, according to this embodiment, as illustrated in FIG. 10, a bias voltage is applied to the electrode layers 22 and 24 such that the line pattern 221a of the electrode layer 22 has an electric potential of 0.4 V, the line pattern 222a has an electric potential of 1 V, and the electrode layer 24 has an electric potential of 0 V. In this case, as illustrated in FIG. 10, a gradient of the electric potential between the line pattern 222a and the electrode layer 24 is larger than a gradient of the electric potential between the line pattern 221a and the electrode layer 24. For this reason, electric charges move as indicated by the dotted lines in both the region between the line patterns 221a and 222a and the electrode layer 24 and the region surrounded by the virtual line.

This is apparently equivalent to an increase of the effective area of the electrode layer 22. For this reason, it is possible to increase the effective area of the radiation detection element 10.

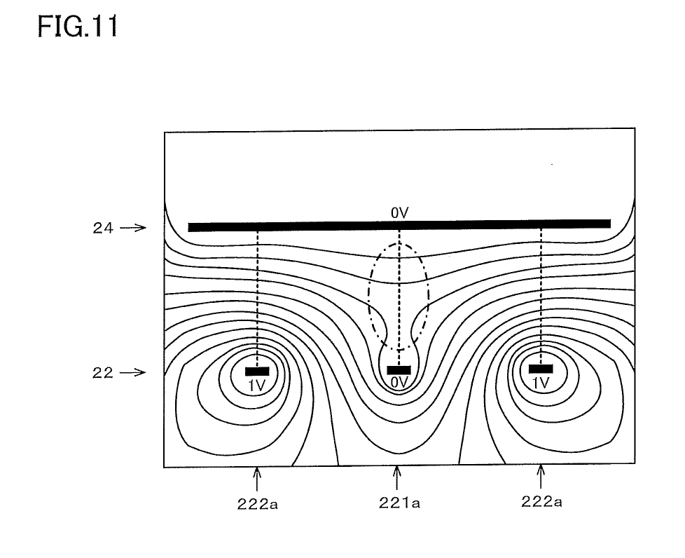

It is difficult to say that the larger difference of the electric potential between the line patterns 221a and 222a, the better. For example, it is assumed that a bias voltage is applied to the electrode layers 22 and 24 such that the line pattern 221a of the electrode layer 22 has an electric potential of 0 V, the line pattern 222a has an electric potential of 1 V, and the electrode layer 24 has an electric potential of 0 V as illustrated in FIG. 11. In this case, a gradient of the electric potential decreases in a portion indicated by the virtual line of FIG. 11, and it is difficult to move the electric charges. For this reason, it is necessary to determine optimum electric potentials in the line patterns 221a and 222a of the electrode layer 22 on the basis of sizes or shapes of the electrode layers 22 and 24, a thickness of the organic layer 23 of the radiation detection element 10, and the like. In the radiation detection element 10 according to this embodiment, the bias voltage is applied to the electrode layers 22 and 24 such that the line pattern 221a of the electrode layer 22 has an electric potential of 0.4 V, the line pattern 222a has an electric potential of 1 V, and the electrode layer 24 has an electric potential of 0 V.

As described above, the electrode layer 22 of the radiation detection element 10 according to this embodiment has the line patterns 221a and 221b. For this reason, even when the size of the radiation detection element 10 increases, the element capacity is maintained in a small value. As a result, it is possible to suppress a decrease of the SN ratio. In addition, the bias voltage is applied to the electrode layers 22 and 24 such that a difference of the electric potential is generated between the line patterns 221a and 221b of the electrode layer 22. For this reason, it is possible to obtain an effect of apparently increasing the effective area of the radiation detection element 10. Therefore, it is possible to increase the size of the semiconductor element without decreasing the SN ratio of the radiation detection element.

In the radiation detection element 10 according to this embodiment, the line patterns 221a and 221b are formed in most of the electrode layer 22 as illustrated in FIG. 3. For this reason, a material that does not have transparency for the light from the scintillator layer 21 may be employed as a material of the electrode layer 22. Therefore, it is not necessary to form the electrode layer 22 using a transparent conductive material such as indium tin oxide (ITO). For this reason, it is possible to reduce a manufacturing cost of the radiation detection element. Furthermore, various conductive materials such as copper or aluminum may be employed as a material of the electrode layer 22. Therefore, it is possible to improve freedom of the element design.

Transmittance of the electrode layer 22 for the light from the scintillator layer 21 is preferably set to 60% or higher. According to this embodiment, the arrangement pitch of the line patterns 221a and 222a is set to 8 μm, and the line width is set to 1 μm. For this reason, the transmittance of the electrode layer 22 becomes 60% or higher.

The radiation detection element 10 according to this embodiment has been described by assuming that the electrode layer 24 is formed of copper. Without limiting thereto, the electrode layer 24 may be formed of a conductive material having excellent reflectivity for the light from the scintillator layer 21. In this case, the light passing through the organic layer 23 is reflected on the electrode layer 24 and is incident to the organic layer 23 again. For this reason, photoelectric conversion efficiency of the organic layer 23 is improved. Furthermore, a reflection film may also be formed between the electrode layer 24 and the organic layer 23.

### Second Embodiment

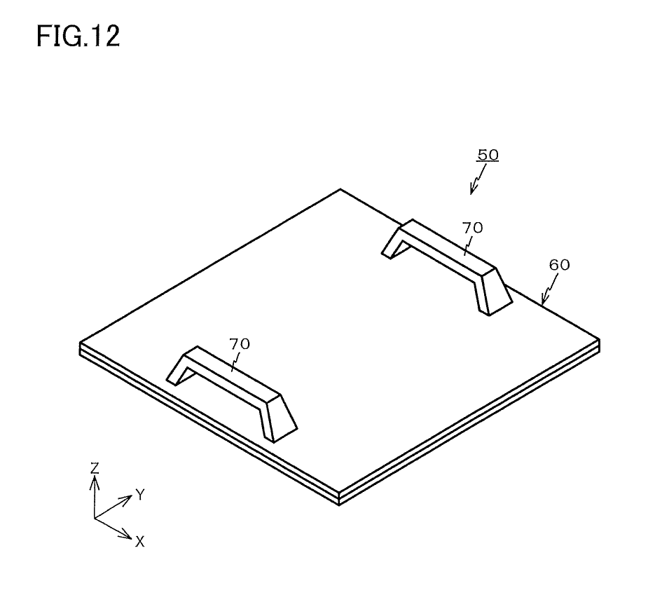

Next, a second embodiment will be described with reference to the accompanying drawings. Like reference numerals denote like elements as in the first embodiment, and they will not be described repeatedly. FIG. 12 is a perspective view illustrating a radiation detection apparatus 50 according to this embodiment. The radiation detection apparatus 50 is, for example, an apparatus for specifying a radioactive ray source or measuring an intensity of the radioactive rays emitted from the radioactive ray source.

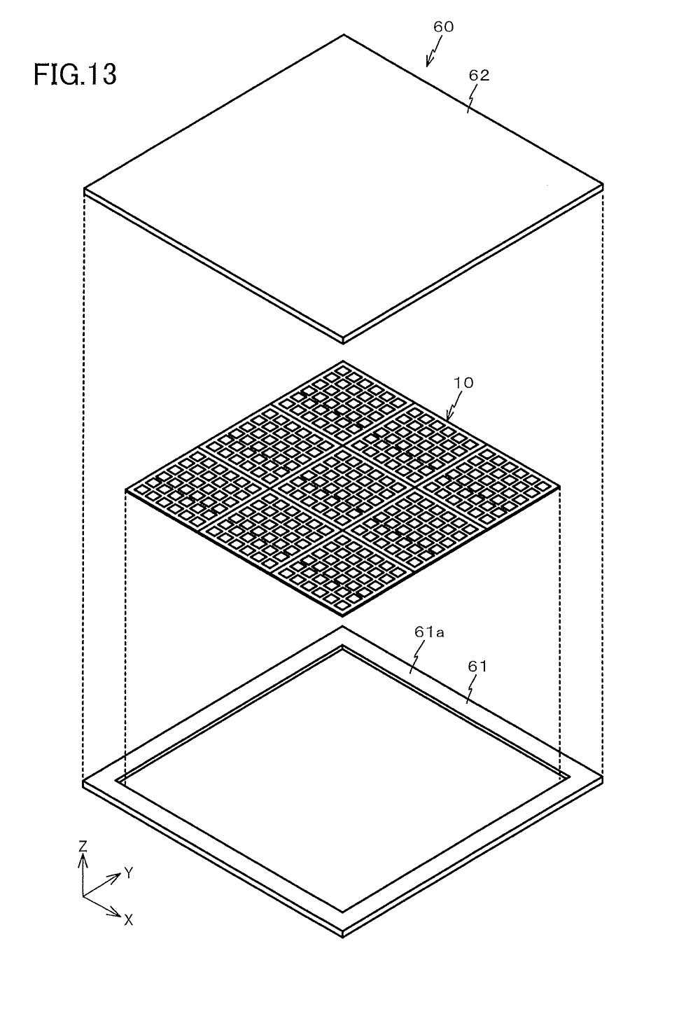

As illustrated in FIG. 12, the radiation detection apparatus 50 includes a detection unit 60 and a handle 70 installed in the detection unit 60. FIG. 13 is an exploded perspective view illustrating the detection unit 60. As illustrated in FIG. 13, the detection unit 60 includes a base 61, nine radiation detection elements 10 housed in the base 61, and a cover 62.

The base 61 is a square plate member, for example, having a length of one side of 30 to 50 cm and a thickness of 2 to 5 mm. The base 61 is provided with a frame 61a formed along an outer periphery. The base 61 is formed of resin such as polyethylene, polyethyleneterephthalate, or polycarbonate. The cover 62 is a member shaped to match the base 61 in size and shape. The cover 62 is also formed of the same material as that of the base 61.

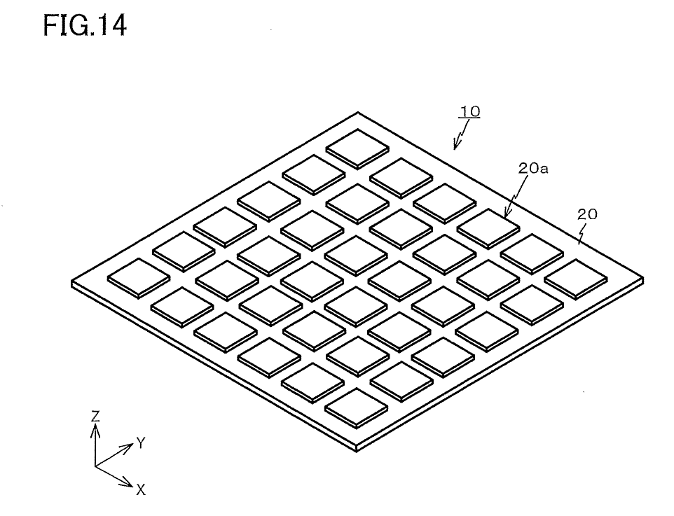

FIG. 14 is a perspective view illustrating the radiation detection element 10. As illustrated in FIG. 14, the radiation detection element 10 according to this embodiment has a substrate 20 and thirty six element portions 20a arranged in a matrix shape having six rows and six columns in the substrate 20. As illustrated in FIG. 2, each element portion 20a has the scintillator layer 21, the electrode layers 22 and 24 stacked on the upper surface of the substrate 20, and the organic layer 23. In addition, the control circuit 30 is provided for each element portion 20a, and each control circuit 30 is formed on the substrate 20. As recognized from FIG. 13, the radiation detection elements 10 are arranged inside of the frame 61a of the base 61 in a matrix shape having three rows and three columns. In addition, the scintillator layer 21 of the radiation detection element 10 is arranged to face the base 61.

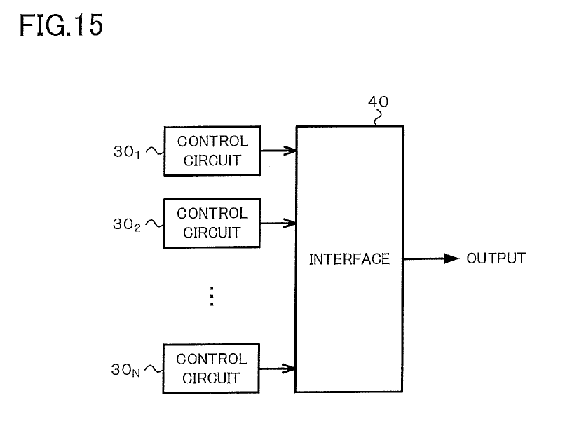

FIG. 15 is a block diagram illustrating a circuit configuration of the radiation detection apparatus 50. As illustrated in FIG. 15, the radiation detection apparatus 50 has an interface 40. The control circuits 30₁ to 30₃₆ provided for each element portion 20a are connected to the interface 40. The detection signals from each control circuit 30 are output to the outside through the interface 40. The interface 40 is installed, for example, in the base 61 and the like.

The base 61, the cover 62, the radiation detection element 10 configured as described above can be integrated to each other by placing the radiation detection element 10 inside of the frame 61a of the base 61 and fixing the outer periphery of the cover 62 to the frame 61a of the base 61. If the base 61 and the cover 62 are integrated to each other, the internal space of the frame 61a becomes a closed space where the radiation detection elements 10 are arranged. The cover 62 may be installed in the base 61, for example, using an adhesive, a bolt-nut set, and the like. In addition, after integration between the cover 62 and the base 61, it is preferable to perform light-shielding treatment in order to prevent visible light from reaching the radiation detection element 10.

After integration between the base 61 and the cover 62, handles 70 are installed in both end portions of the Y-direction of the detection unit 60 as illustrated in FIG. 12. For example, a bolt or the like may be used to install the handles 70.

The radiation detection apparatus 50 configured as described above has, for example, handles 70 used to press the detection unit 60 toward a target object serving as a radioactive ray source. As a radioactive ray is incident to the radiation detection apparatus 50, the detection signal is output to the outside through the interface 40 of FIG. 15.

As described above, it is possible to increase the size of the radiation detection element 10 used in the radiation detection apparatus 50 according to this embodiment without decreasing the SN ratio. Therefore, it is possible to reduce the number of radiation detection elements 10 per detection area while maintaining the radioactive ray detection accuracy. Therefore, it is possible to simplify the apparatus configuration and reduce the manufacturing cost of the apparatus.

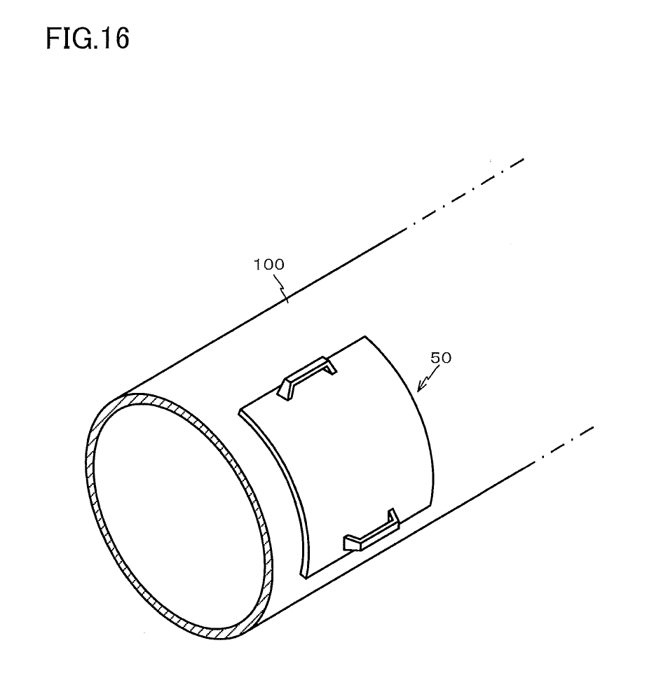

If the base 61, the cover 62, and the substrate 20 of the radiation detection element 10 are formed of a flexible material in the radiation detection apparatus 50 according to the aforementioned embodiment, it is possible to use the radiation detection apparatus 50 by curving it as illustrated in FIG. 16. As a result, it is possible to use a radioactive ray source having a curved surface such as a pipe or a tank as a detection target 100.

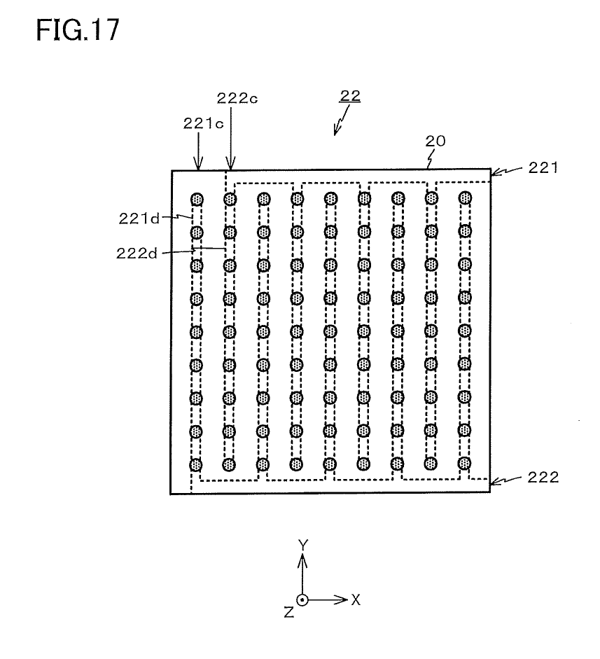

While the embodiments of the disclosure have been described hereinbefore, the disclosure is not limited to such embodiments. For example, in the aforementioned embodiments, the electrode patterns 221 and 222 of the electrode layer 22 are the line patterns 221a and 222a as illustrated in FIG. 3. Alternatively, without limiting thereto, for example, the electrode patterns 221 and 222 of the electrode layer 22 may be dot patterns 221c and 222c arranged in an alternating manner in a matrix shape as illustrated in FIG. 17. In this case, the bias voltage is applied to the dot patterns 221c and 222c through the conductor patterns 221d and 222d provided on the lower surface (−Z-side surface) of the substrate 20. As a result, it is possible to obtain effects similar to those of a case where the electrode patterns 221 and 222 are line patterns 221a and 221b.

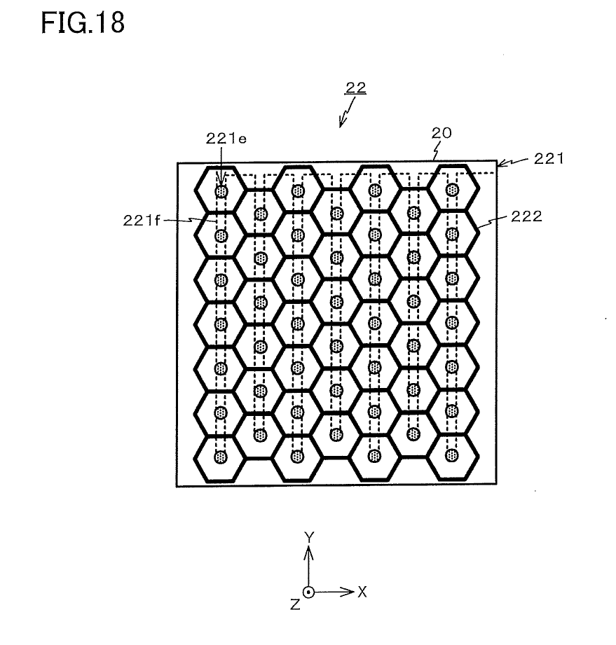

In addition, as illustrated in FIG. 18, the electrode pattern 221 of the electrode layer 22 may be a dot pattern 221e, and the electrode pattern 222 may be a honeycomb pattern that surrounds the dot pattern 221e. A bias voltage is applied to the dot pattern 221e through the conductor pattern 221f provided on the lower surface (−Z-side surface) of the substrate 20. As a result, it is possible to obtain effects similar to those of a case where the electrode patterns 221 and 222 are line patterns 221a and 221b.

In the aforementioned embodiment, the electrode layer 22 has eleven line patterns 221a and 222a extending in parallel to the Y-axis as illustrated in FIG. 3. In practice, the electrode layer 22 has a large number of line patterns 221a and 222a more than eleven. Similarly, the electrode layer 22 relating to the dot patterns 221c, 222c, and 221e of FIGS. 17 and 18 has a large number of dot patterns more than the number shown in the drawings.

In the aforementioned embodiment, one side of the radiation detection element 10 has a length of approximately 10 mm. Alternatively, without limiting thereto, one side of the radiation detection element 10 may have a length longer than 10 mm.

In the aforementioned embodiment, the radiation detection element 10 used in the radiation detection apparatus 50 has thirty six element portions 20a. Alternatively, without limiting thereto, thirty seven or more radiation detection elements 10 may also be provided. In addition, thirty five or less element portions 20a may also be provided.

### <Modifications>

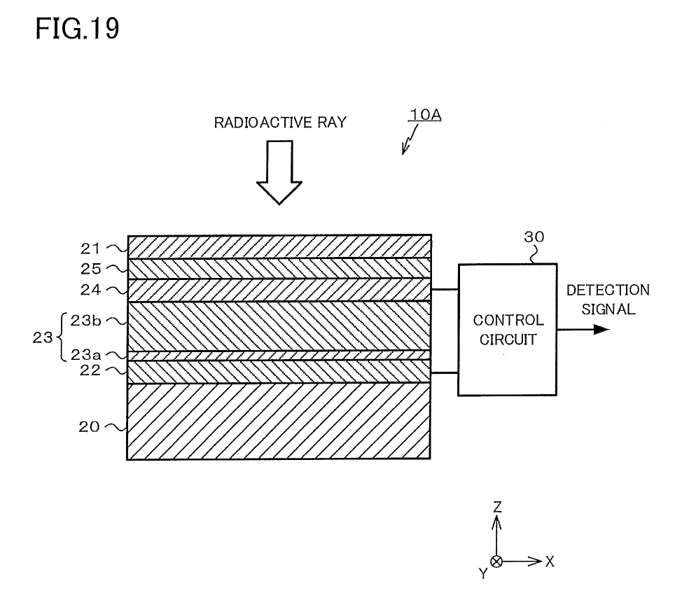

In the aforementioned embodiment, the radiation detection element 10 having the scintillator layer 21 is provided on the lower surface of the substrate 20 as illustrated in FIG. 2. Alternatively, without limiting thereto, the scintillator layer 21 may be provided over the electrode layer 24 as in the radiation detection element 10A illustrated in FIG. 19.

In the radiation detection element 10A, the scintillator layer 21 is formed on the upper surface of the electrode layer 24 by interposing an insulation film 25. The insulation film 25 may include, for example, a silicon oxynitride film (SiON), a silicon nitride film (SiN), a silicon oxide film (SiO), or the like. In the radiation detection element 10A, the electrode layer 24 has a pattern (solid pattern). For this reason, the electrode layer 24 may be formed of a transparent conductive material such as ITO.

In the radiation detection element 10A, for example, if a radioactive ray is incident to the scintillator layer 21 from the top as indicated by the white arrow of FIG. 19, the scintillator layer 21 emits green light. The light from the scintillator layer 21 is incident to the organic layer 23 through the insulation film 25 and the electrode layer 24. The organic layer 23 generates movable electric charges depending on the energy of the incident light. A voltage of the electrode layer 24 increases by virtue of these electric charges.

As the voltage of the electrode layer 24 increases, a detection signal having a value corresponding to an increase of the voltage is output from the control circuit 30. The detection signal becomes a pulse signal having a value steeply increasing in synchronization with the incidence timing of the radioactive ray. Therefore, it is possible to measure an intensity of the radioactive ray incident to the radiation detection element 10 by counting the number of pulses of the detection signal.

Using the radiation detection element 10A according to the modification, it is possible to detect a radioactive ray incident from the top of the substrate 20 with high accuracy. Note that the electrode layer 24 of the radiation detection element 10A is provided on the upper surface of the organic layer 23, and the electrode layer 22 having a line pattern is provided on the lower surface of the organic layer 23. Alternatively, without limiting thereto, the electrode layer 22 may be provided on the upper surface of the organic layer 23, and the electrode layer 24 may be provided on the lower surface of the organic layer 23.

In the embodiments and the modifications described above, the radiation detection element 10 is an indirect conversion type radiation detection element provided with the scintillator layer 21. Alternatively, without limiting thereto, the radiation detection element 10 or 10A may be a direct conversion type radiation detection element having no scintillator layer 21. In the indirect conversion type radiation detection element, the organic layer is excited by the light from the scintillator as described above. In contrast, in the indirect conversion type radiation detection element, the organic layer is excited directly by an incident radioactive ray. For this reason, the direct conversion type radiation detection element typically has higher radioactive ray detection efficiency.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

1. A radiation detection element comprising:
an organic layer configured to generate an electric charge by receiving an incident radioactive ray;
a first electrode layer arranged in one side of the organic layer; and
a second electrode layer arranged in another side of the organic layer to face the first electrode layer, the second electrode layer having a first electrode pattern and a second electrode pattern spaced from the first electrode pattern,
wherein a first voltage is applied to the first electrode layer, a second voltage higher than the first voltage is applied to the first electrode pattern, and a third voltage higher than the first voltage and lower than the second voltage is applied to the second electrode pattern, and
the first electrode layer, the first electrode pattern, and the second electrode pattern form a potential gradient between the first electrode layer and the first electrode pattern, and the potential gradient is larger than a potential gradient between the first electrode layer and the second electrode pattern.

2. (canceled)

3. The radiation detection element according to claim 1, further comprising a detection circuit configured to detect a pulse current flowing to the first electrode layer.

4. The radiation detection element according to claim 1, wherein the first electrode pattern and the second electrode pattern are line patterns, and
the first electrode pattern and the second electrode pattern are arranged in parallel with each other at equal intervals.

5. The radiation detection element according to claim 4, wherein the first electrode pattern and the second electrode pattern are arranged in an alternating manner.

6. The radiation detection element according to claim 1, wherein the first electrode pattern and the second electrode pattern are dot patterns arranged in an alternating manner.

7. The radiation detection element according to claim 1, wherein the first electrode pattern is surrounded by the second electrode pattern.

8. The radiation detection element according to claim 1, further comprising a scintillator layer stacked on the organic layer by interposing the second electrode layer,
wherein the organic layer generates the electric charge in response to light emitted from the scintillator layer by receiving an incident radioactive ray.

9. A radiation detection apparatus comprising:
a plurality of radiation detection elements, each including:
an organic layer configured to generate an electric charge by receiving an incident radioactive ray,
a first electrode layer arranged in one side of the organic layer, and
a second electrode layer arranged in another side of the organic layer to face the first electrode layer, the second electrode layer having a first electrode pattern and a second electrode pattern spaced from the first electrode pattern; and
a substrate on which the radiation detection elements are arranged in an array shape,
wherein a first voltage is applied to the first electrode layer, a second voltage higher than the first voltage is applied to the first electrode pattern, and a third voltage higher than the first voltage and lower than the second voltage is applied to the second electrode pattern, and
the first electrode layer, the first electrode pattern, and the second electrode pattern form a potential gradient between the first electrode layer and the first electrode pattern, and the potential gradient is larger than a potential gradient between the first electrode layer and the second electrode pattern.
